(19) United States
(12) Patent Application Publication
(10) Pub. No.: US 2026/0035544 A1
(43) Pub. Date: Feb. 5, 2026

(54) HEAT DISSIPATION MATERIAL, METHOD OF MANUFACTURING SAME, AND ELECTROSTATIC CHUCK

(71) Applicants: SEMES CO., LTD., Cheonan-si (KR); KOREA UNIVERSITY RESEARCH AND BUSINESS FOUNDATION, Seoul (KR)

(72) Inventors: So Hyung JIONG, Cheonan-si (KR); Ja Myung GU, Cheonan-si (KR); Won Joon CHOI, Seoul (KR)

(73) Assignees: SEMES CO., LTD., Cheonan-si (KR); KOREA UNIVERSITY RESEARCH AND BUSINESS FOUNDATION, Seoul (KR)

(21) Appl. No.: 19/246,949

(22) Filed: Jun. 24, 2025

(30) Foreign Application Priority Data
Aug. 2, 2024 (KR) 10-2024-0103148

(51) Int. Cl. C08K 7/02; C08K 3/04; C08K 3/38; H01L 21/683

(52) U.S. Cl. CPC C08K 7/02; C08K 3/041; C08K 3/38; H01L 21/6833; C08K 2003/385; C08K 2201/001; C08K 2201/003

(57) ABSTRACT

Disclosed are a heat dissipation material that enables temperature to be uniformly distributed over the entire area of a substrate, a method of manufacturing the heat dissipation material, and an electrostatic chuck with the heat dissipation material applied thereto. The method of manufacturing the heat dissipation material provided to an electrostatic chuck supporting a substrate in a substrate processing apparatus using plasma includes forming a first particle dispersion treated to charge the surface of isotropic particles with a first electric potential, forming a second particle dispersion treated to charge the surface of anisotropic particles with a second electric potential different from the first electric potential, and forming hybrid particles including the isotropic particles and the anisotropic particles bound by electrostatic force by mixing the first particle dispersion and the second particle dispersion.

### CROSS REFERENCE TO RELATED APPLICATION

The present application claims priority to Korean Patent Application No. 10-2024-0103148, filed Aug. 2, 2024, the entire contents of which are incorporated herein for all purposes by this reference.

### BACKGROUND

### Technical Field

The present disclosure relates to a heat dissipation material provided to a substrate processing apparatus using plasma, a method of manufacturing the heat dissipation material, and an electrostatic chuck with the heat dissipation material applied thereto.

### Description of the Related Art

Semiconductor (or display) manufacturing is a process of manufacturing a semiconductor device on a substrate (e.g., a wafer), and includes, for example, exposure, deposition, etching, ion implantation, cleaning, and the like. In order to perform individual manufacturing processes, semiconductor manufacturing facilities responsible for respective processes are installed in a clean room of a semiconductor manufacturing plant, and process treatment is performed on substrates fed into the semiconductor manufacturing facilities.

In semiconductor manufacturing, processes using plasma, such as etching, deposition, etc., are widely used. The plasma treatment process is carried out by placing a substrate at the bottom in a plasma treatment space and applying an RF (radio frequency) signal by electrodes located at the top or bottom along with supply of a fluid for plasma treatment.

In order to control plasma distribution and substrate processing uniformity in a substrate processing apparatus using plasma, heating and cooling devices are provided to an electrostatic chuck supporting the substrate. The temperature of the substrate is controlled using the heating and cooling devices provided to the electrostatic chuck. As such, it is important that the temperature of the electrostatic chuck be uniformly transferred to the substrate. However, heat caused by plasma energy may be usually concentrated in the edge area of the substrate, causing a large temperature difference between the center area and the edge area of the substrate.

### SUMMARY

The present disclosure is intended to provide a heat dissipation material that enables temperature to be uniformly distributed over the entire area of a substrate, a method of manufacturing the heat dissipation material, and an electrostatic chuck with the heat dissipation material applied thereto.

The present disclosure provides a method of manufacturing a heat dissipation material provided to an electrostatic chuck supporting a substrate in a substrate processing apparatus using plasma, including forming a first particle dispersion treated to charge a surface of isotropic particles with a first electric potential, forming a second particle dispersion treated to charge a surface of anisotropic particles with a second electric potential different from the first electric potential, and forming hybrid particles including the isotropic particles and the anisotropic particles bound by electrostatic force by mixing the first particle dispersion and the second particle dispersion.

In an embodiment of the present disclosure, the isotropic particles may include a metal including at least one of Cu, Al, or Ag, or a ceramic including at least one of Al2O3, AlN, or SiC.

In an embodiment of the present disclosure, the anisotropic particles may be BN (boron nitride), or may include at least one of CNTs (carbon nanotubes) or CNF (cellulose nanofiber).

In an embodiment of the present disclosure, forming the second particle dispersion may include attaching at least one functional group of OH-, F-, or NH2- to the surface of the anisotropic particles and performing surface modification by exfoliating a hexagonal crystal plane from the anisotropic particles with the functional group attached thereto.

In an embodiment of the present disclosure, a major axis length of the anisotropic particles may be 1 nm to 1000 nm.

In an embodiment of the present disclosure, an aspect ratio of the anisotropic particles may be 10 to 1000.

In an embodiment of the present disclosure, a grain size of a (002) plane of the anisotropic particles may be 5 Å to 500 Å in X-ray diffraction analysis.

In an embodiment of the present disclosure, a volume ratio of the isotropic particles to the anisotropic particles in the hybrid particles may be 2:98 to 98:2.

In an embodiment of the present disclosure, the heat dissipation material may be manufactured in the form of a grease, a gap filler, or an adhesive by mixing a polymer matrix and a solvent with the hybrid particles to afford a slurry and aging the slurry.

In an embodiment of the present disclosure, the heat dissipation material may be manufactured in the form of a film, a sheet, a pad, or a plate by mixing a polymer matrix and a solvent with the hybrid particles to afford a slurry and subjecting the slurry to extrusion molding, compounding, thermoforming, or compression coating.

In an embodiment of the present disclosure, the heat dissipation material may be manufactured in the form of a sintered body by subjecting the hybrid particles to a hot isostatic process (HIP) or plasma spraying.

In addition, the present disclosure provides a heat dissipation material provided to an electrostatic chuck supporting a substrate in a substrate processing apparatus using plasma, including hybrid particles formed by mixing a first particle dispersion treated to charge a surface of isotropic particles with a first electric potential and a second particle dispersion treated to charge a surface of anisotropic particles with a second electric potential different from the first electric potential and configured to include the isotropic particles and the anisotropic particles bound by electrostatic force.

In addition, the present disclosure provides an electrostatic chuck supporting a substrate in a substrate processing apparatus using plasma, including a base plate made of a metal material having a cooling path formed inside through which a cooling fluid flows, an adhesive layer disposed on the base plate, and a support plate made of a ceramic material adhered onto the base plate through the adhesive layer and having a heater installed inside for heating the substrate. As such, a heat dissipation material may be attached to transfer heat from the support plate or the base plate to the substrate.

### BRIEF DESCRIPTION OF THE DRAWINGS

FIG. 1 shows a schematic structure of a substrate processing apparatus according to the present disclosure.

FIGS. 2A to 2D show heat dissipation materials according to comparative examples.

FIG. 3 is a flowchart showing a process of manufacturing a heat dissipation material according to the present disclosure.

FIGS. 4A to 4C show the process of manufacturing a heat dissipation material according to the present disclosure.

FIGS. 5 and 6 show the structures of the heat dissipation material according to the present disclosure.

FIG. 7 shows electron dispersive spectroscopy (EDS) images of hybrid particles depending on a mass ratio of isotropic particles to anisotropic particles.

### DETAILED DESCRIPTION

Hereinafter, embodiments of the present disclosure will be described in detail with reference to the appended drawings so as to easily perform the present disclosure by those having ordinary skill in the art to which the present disclosure pertains. The present disclosure may be embodied in many different forms and is not limited to the embodiments described herein.

In order to clearly explain the present disclosure, parts that are not relevant to the description are omitted, and identical or similar components are assigned the same reference numerals throughout the specification.

Also, in various embodiments, components having the same configuration are described only in representative embodiments using the same reference numerals, and in other embodiments, only configurations different from the representative embodiments are described.

Throughout the specification, when a part is said to be “connected (or coupled)” to another part, this includes not only cases where it is “directly connected (or coupled)” but also cases where it is “indirectly connected (or coupled)” with other parts therebetween. Also, when a part is said to “include” a component, this does not mean that it excludes other components, but rather that it may further include other components, unless specifically stated otherwise. Herein, “A to B” (A and B are any number) refers to any number greater than or equal to A and less than or equal to B.

Unless defined otherwise, all terms used herein, including technical or scientific terms, have the same meaning as commonly understood by those having ordinary skill in the art to which the present disclosure pertains. Terms defined in commonly used dictionaries should be interpreted as having a meaning consistent with their meaning in the context of the relevant art, and will not be interpreted in an idealized or overly formal sense, unless expressly defined otherwise herein.

As a semiconductor manufacturing facility of the present embodiment, a substrate processing apparatus may be used to perform a process on a substrate such as a semiconductor wafer or a flat display panel. In particular, the substrate processing apparatus 1 of the present embodiment is configured to perform an etching or deposition process on a substrate using plasma.

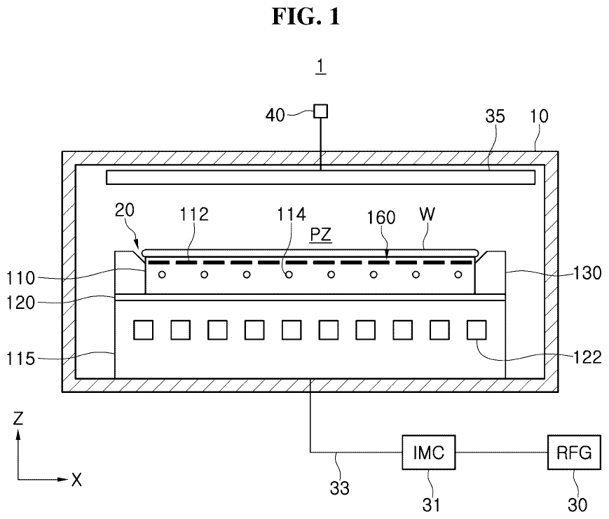

FIG. 1 shows a schematic structure of a substrate processing apparatus 1 according to the present disclosure. The substrate processing apparatus 1 using plasma according to the present disclosure includes a chamber 10 configured to form a plasma treatment space PZ for a substrate W, an electrostatic chuck 20 located at the bottom of the chamber 10, and an RF power source 30 configured to supply power for generating plasma in the treatment space PZ to a base plate 115 of the electrostatic chuck 20.

The chamber 10 provides a plasma treatment space PZ for the substrate W, and parts for plasma treatment are installed inside the chamber 10. An upper electrode 35 and a gas supply unit are located at the top of the chamber 10, and the electrostatic chuck 20 is located at the bottom of the chamber 10. A plate may be located at the top of the chamber 10 to separate the upper space where the upper electrode 35 is located from the plasma treatment space PZ. The upper electrode 35 may be grounded. The upper electrode 35 may be a showerhead configured to dispense a processing gas and supply the same to the treatment space PZ. A gas supply source 40 may be configured to supply the processing gas to the upper electrode 35, and the processing gas may be supplied to the treatment space PZ through the upper electrode 35.

The electrostatic chuck 20 is located below the treatment space PZ. The electrostatic chuck 20 may include a base plate 115, a support plate 110, and an edge ring 130. The electrostatic chuck 20 is provided at the bottom of the chamber 10 and serves to support the substrate W using electrostatic force. In the electrostatic chuck 20, electrodes 112 may be provided inside the support plate 110 to bring the substrate W into close contact with the support plate 110 using electrostatic force. The electrostatic chuck 20 may function as a lower electrode to generate plasma. An adhesive layer 120 may be disposed between the base plate 115 and the support plate 110. The adhesive layer 120 serves to fix the base plate 115 and the support plate 110 to each other. The adhesive layer 120 may be made of a silicone material.

The electrostatic chuck 20 includes the support plate 110 on which a substrate W for plasma treatment is placed and in which heaters 114 are embedded, and the base plate 115 configured to support the bottom of the support plate 110 and provided with a cooling path 122 formed inside through which a cooling fluid flows.

The support plate 110 is a structure that supports the substrate W from below, and includes the electrodes 112 and heaters 114 formed inside. The support plate 110 may be made of a ceramic material (e.g., quartz).

The base plate 115 is provided in the form of a disc made of a metal (e.g., Al) material. The base plate 115 may be composed of a lower area having a predetermined diameter and an upper area having a smaller diameter than the lower area. The cooling path 122 may be formed in the lower area of the base plate 115. The upper area of the base plate 115 may be joined to the support plate 110. The base plate 115 may have a shape in which the lower area protrudes. The edge ring 130 for plasma control of the edge portion of the substrate W may be provided on the protruding portion of the base plate 115.

A coating layer made of alumina (Al₂O₃) may be formed on the outer surface of the base plate 115. The coating layer serves to prevent the base plate 115 made of metal (e.g., Al) from being exposed to an external environment, especially plasma. Also, the adhesive layer 120 is formed between the support plate 110 and the base plate 115 to adhere the support plate 110 and the base plate 115.

The RF power source 30 serves to apply power to the base plate 115 of the electrostatic chuck 20 corresponding to the lower electrode. Such an RF power source 30 may be provided to control the characteristics of plasma. The RF power source 30 may be provided to control, for example, ion bombardment energy. In FIG. 1, the RF power source 30 is shown as being connected to the lower electrode, but the RF power source 30 may be connected to both the upper electrode 35 and the electrostatic chuck 20. Alternatively, an upper power source connected to the upper electrode 35 and a lower power source connected to the electrostatic chuck 20 may be separately configured. Also, a plurality of upper power sources may be provided, and a plurality of lower power sources may be provided. When the upper power sources are provided, a matching network electrically connected to the upper power sources may be provided to the substrate processing apparatus 1. The matching network may serve to match frequency powers of different magnitudes input from the upper and lower power sources and apply the same to the upper electrode 35 and the electrostatic chuck 20. Meanwhile, an impedance matching circuit 31 may be provided in an RF cable 33 between the RF power source 30 and the base plate 115 to achieve impedance matching.

The upper electrode 35 serves to generate plasma from gas remaining in the plasma treatment space PZ. Here, the plasma treatment space PZ is a space located above the electrostatic chuck 20 in the internal space of the chamber 10. The upper electrode 35 is able to generate plasma in an inductively coupled plasma or capacitively coupled plasma manner. The upper electrode 35 may be grounded. Alternatively, an upper RF power source may be connected to the upper electrode 35, and an electromagnetic field may be generated from power supplied from the upper RF power source. A matching circuit for impedance matching may be configured between the upper electrode 35 and the RF power source 30.

The gas supply source 40 serves to supply an etching gas used to process the substrate W as a processing gas. By the gas supply source 40, gas including a fluorine component (e.g., gas including SF₆ or CF₄) as an etching gas may be supplied to the upper electrode 35.

As the gas supply unit, the RF power source 30 may be installed to face the electrostatic chuck 20 in the vertical direction Z at the top of the chamber 10. The gas supply unit may have a plurality of gas injection holes to inject gas to the inside of the chamber 10. The gas supply unit may be provided to have a larger diameter than the electrostatic chuck 20 in the horizontal direction X. The gas supply unit may be a showerhead including a plurality of gas injection holes. Also, the gas supply unit may be a structure having one or more gas supply nozzles.

In order to achieve uniform plasma treatment on the substrate W, it is important to precisely control the temperature over the entire area of the substrate W. For example, the temperature of each area of the substrate W may be controlled by the heaters 114 provided to the support plate 110 and a coolant flowing along the cooling path 122. In order to achieve precise temperature control of the substrate W, it is important that heat be uniformly transferred from the electrostatic chuck 20 to the substrate W. To improve the heat transfer efficiency of the electrostatic chuck 20, a heat dissipation material may be applied to the electrostatic chuck 20.

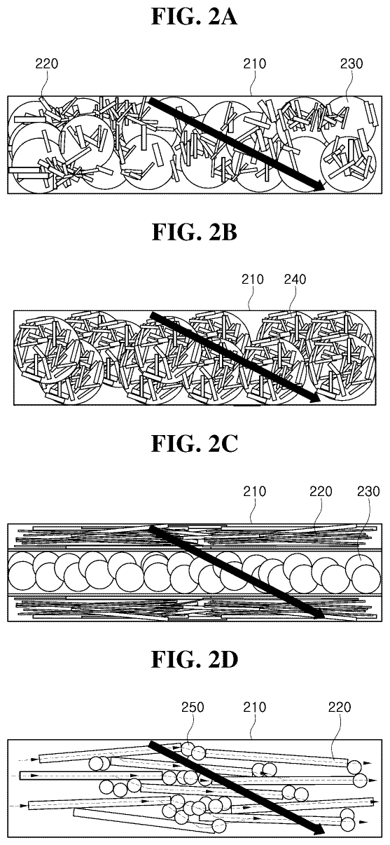

FIGS. 2A to 2D show heat dissipation materials according to comparative examples. As comparative examples, FIG. 2A shows a polymer complex composed of a mixture of isotropic particles 230 and anisotropic particles 240 in a polymer matrix 210, FIG. 2B shows a polymer complex composed of agglomerates 220 of anisotropic particles 240 in a polymer matrix 210, FIG. 2C shows a polymer complex composed of a multilayer film including isotropic particles 230 and anisotropic particles 240 in a polymer matrix 210, and FIG. 2D shows a polymer complex composed of a mixture of isotropic particles 230 or anisotropic particles 240 and nanoparticles 250. In FIGS. 2A to 2D, the arrow indicates the direction in which heat is transferred.

In the polymer complex composed of the mixture of isotropic particles 230 and anisotropic particles 240 in the polymer matrix 210 as shown in FIG. 2A, the isotropic particles 230, the anisotropic particles 240, the polymer matrix 210, and a solvent may be mixed in a predetermined mixing ratio to prepare a slurry, from which a heat dissipation material may then be manufactured in the form of a grease, gap filler, adhesive, etc. through aging, or in the form of a film, sheet, pad, plate, etc. through film formation, extrusion molding, compounding, thermoforming, extrusion coating, etc. However, when the isotropic particles 230 and the anisotropic particles 240 are simply mixed, local agglomeration of the anisotropic particles 240 may occur in preparing the slurry during the subsequent heat dissipation material manufacturing processes (slurry preparation, molding, drying, etc.), or the anisotropic particles 240 may become oriented in a certain direction due to the pressure applied during molding, resulting in deteriorated performance.

In the polymer complex composed of the agglomerates 220 of anisotropic particles 240 in the polymer matrix 210 as shown in FIG. 2B, the agglomerates 220 of anisotropic particles 240 may be manufactured by firing the anisotropic particles 240 at a high temperature in a non-oxidizing atmosphere followed by crushing and sorting, or by mixing the anisotropic particles 240 with a small amount of a binder such as a polymer resin followed by spraying into droplets using a spray method and drying. The anisotropic agglomerates, the polymer matrix 210, and the solvent may be mixed in a predetermined mixing ratio to prepare a slurry, from which a heat dissipation material may then be manufactured in the form of a grease, gap filler, adhesive, etc., or in the form of a film, sheet, pad, plate, etc. through film formation, extrusion molding, compounding, thermoforming, extrusion coating, etc. However, there are problems in that (i) it is difficult to control the size of the agglomerates to 10 μm or less, (ii) the agglomerates may easily break apart in the subsequent heat dissipation material manufacturing processes (slurry preparation, drying, hot pressing, etc.), and (iii) the manufacturing cost may increase because relatively expensive anisotropic particles have to be manufactured through a separate agglomeration process (heat treatment followed by crushing, sorting, or spray granulation).

In the polymer complex composed of the multilayer film including isotropic particles 230 and anisotropic particles 240 in the polymer matrix 210 as shown in FIG. 2C, the multilayer film may be manufactured by mixing the isotropic particles 230, the polymer matrix 210, and the solvent in a predetermined mixing ratio to prepare a slurry, forming the slurry into a film, and then pouring and stacking a slurry composed of the anisotropic particles 240, the polymer matrix 210, and the solvent on the film, or by attaching an anisotropic film and an isotropic film, which are separately manufactured in the above-described manner. However, there is a problem in that manufacturing the multilayer film using a film formation process including coating solution preparation, coating, drying, and releasing is expensive. Moreover, there are many technical challenges in controlling the properties and thickness of the film, so commercialization may become very difficult.

In the polymer complex composed of the mixture of isotropic particles 230 or anisotropic particles 240 and nanoparticles 250 as shown in FIG. 2D, the isotropic particles 230 or the anisotropic particles 240, the nanoparticles 250, the polymer matrix 210, and the solvent may be mixed in a predetermined mixing ratio to prepare a slurry, from which a heat dissipation material may then be manufactured in the form of a grease, gap filler, adhesive, etc. through aging, or in the form of a film, sheet, pad, plate, etc. through film formation, extrusion molding, compounding, thermoforming, extrusion coating, etc. However, commercialization may become difficult due to the high price of nanomaterials (metals, oxides, carbon, diamond) used and the difficulty in dispersion control.

Taking into consideration the problems in various comparative examples as described above, the present disclosure provides a heat dissipation material or a thermoelectric material in which heat transfer efficiency is improved in horizontal and vertical directions and manufacture thereof is easy, a method of manufacturing the heat dissipation material, and an electrostatic chuck 20 with the heat dissipation material applied thereto.

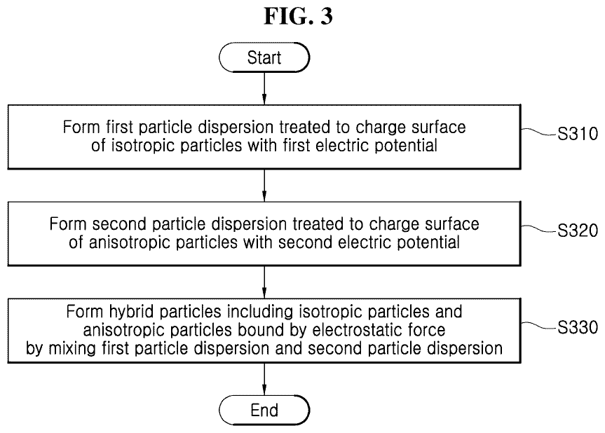

FIG. 3 is a flowchart showing a process of manufacturing a heat dissipation material according to the present disclosure. The method of manufacturing the heat dissipation material provided to an electrostatic chuck 20 supporting a substrate W in a substrate processing apparatus 1 using plasma according to the present disclosure includes forming a first particle dispersion L1 treated to charge the surface of isotropic particles 310 with a first electric potential (S310), forming a second particle dispersion L2 treated to charge the surface of anisotropic particles 320 with a second electric potential different from the first electric potential (S320), and forming hybrid particles 330 including the isotropic particles 310 and the anisotropic particles 320 bound by electrostatic force by mixing the first particle dispersion L1 and the second particle dispersion L2 (S330).

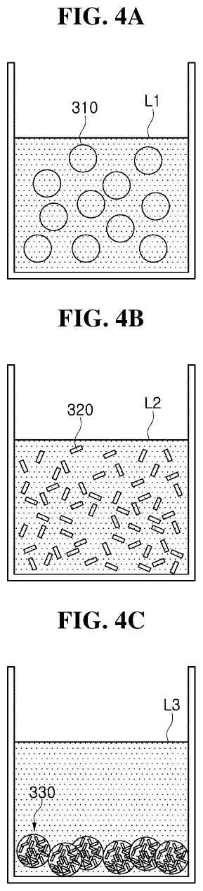

In S310, the first particle dispersion L1 treated to charge the surface of isotropic particles 310 with a first electric potential is formed. As shown in FIG. 4A, the first particle dispersion L1 may include the isotropic particles 310. The isotropic particles 310 are particles in which individual particles have a uniform shape without directionality. The isotropic particles 310 may be a metal including at least one of copper (Cu), aluminum (Al), or silver (Ag). Alternatively, the isotropic particles 310 may be a ceramic including at least one of alumina (Al₂O₃), aluminum nitride (AlN), or silicon carbide (SiC). An electrostatic charge corresponding to the first electric potential may be applied to the isotropic particles 310. The first electric potential may be either positive or negative.

In S320, the second particle dispersion L2 treated to charge the surface of the anisotropic particles 320 with a second electric potential different from the first electric potential is formed. As shown in FIG. 4B, the second particle dispersion L2 may include the anisotropic particles 320. The anisotropic particles 320 are particles in which individual particles have an elongated shape in a specific direction. The anisotropic particles 320 may be BN (boron nitride) having a hexagonal crystal structure. Alternatively, the anisotropic particles 320 may be a carbon-based material, such as carbon nanotubes (CNTs) or cellulose nanofiber (CNF), or a mixture of carbon-based materials. The second electric potential may be either positive or negative. The first and second electric potentials may have opposite polarities.

Forming the second particle dispersion L2 (S320) may include attaching at least one functional group of OH-, F-, or NH2- to the surface of the anisotropic particles 320 and performing surface modification by exfoliating a hexagonal crystal plane from the anisotropic particles 320 with the functional group attached thereto. In performing the surface modification, chemical treatment may be carried out to exfoliate the hexagonal crystal plane. Alternatively, a mechanical external force such as sonication or ball milling may be applied along with chemical treatment to exfoliate the hexagonal crystal plane during surface modification.

The major axis length of the anisotropic particles 320 may be 1 nm to 1000 nm. The aspect ratio of the anisotropic particles 320 may be 10 to 1000. In X-ray diffraction analysis, the grain size of the (002) plane of the anisotropic particles 320 may be 5 Å to 500 Å.

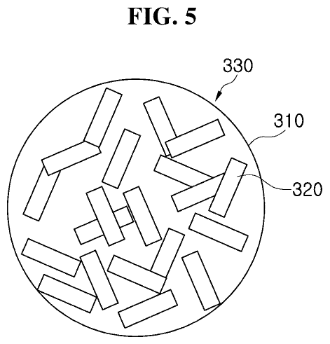

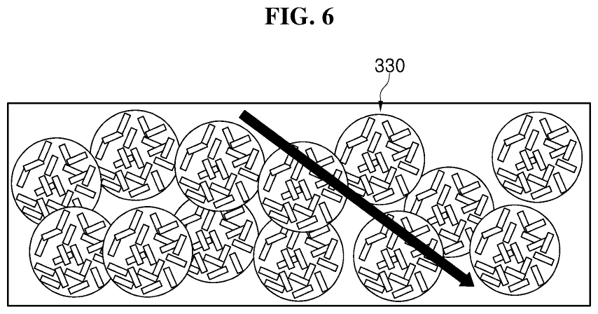

In S330, the hybrid particles 330 including the isotropic particles 310 and the anisotropic particles 320 bound by electrostatic force by mixing the first particle dispersion L1 and the second particle dispersion L2 are formed. As shown in FIG. 4C and FIGS. 5 and 6, the hybrid particles 330 may be formed by binding the isotropic particles 310 and the anisotropic particles 320 to each other. In FIG. 6, the arrow indicates the direction in which heat is transferred. The isotropic particles 310 and the anisotropic particles 320 may be bound to each other by the electrostatic force caused by the difference between the first electric potential charged to the isotropic particles 310 and the second electric potential charged to the anisotropic particles 320. Specifically, the dispersion L1 of isotropic particles 310 and the dispersion L2 of anisotropic particles 320, the surfaces of which are modified to have different zeta potential values, are separately prepared, and then mixed, thereby manufacturing hybrid particles 330 including the particles attached to each other by electrostatic force.

As such, the difference in zeta potential between the dispersion L1 of isotropic particles 310 and the dispersion L2 of anisotropic particles 320 may be set such that binding by electrostatic force is possible. For example, the difference in zeta potential between the dispersion L1 of isotropic particles 310 and the dispersion L2 of anisotropic particles 320 may be tens of mV or more, for example, 10 mV to 50 mV. The volume ratio of the isotropic particles 310 to the anisotropic particles 320 may fall in the range of 2:98 to 98:2.

After formation of the hybrid particles 330 as described above, a polymer composite or a sintered body using the hybrid particles 330 may be manufactured.

In one embodiment, a heat dissipation material may be manufactured in the form of a grease, gap filler, or adhesive by mixing a polymer matrix and a solvent with the hybrid particles 330 to prepare a slurry followed by aging.

In one embodiment, a heat dissipation material may be manufactured in the form of a film, sheet, pad, or plate by mixing a polymer matrix and a solvent with the hybrid particles 330 to prepare a slurry followed by extrusion molding, compounding, thermoforming, or compression coating.

In one embodiment, a heat dissipation material may be manufactured in the form of a sintered body by subjecting the hybrid particles 330 to a hot isostatic process (HIP) or plasma spraying.

The present disclosure provides hybrid particles 330 capable of controlling the directionality of heat flow by uniformly attaching nanoparticles having anisotropic thermal properties to the surface of particles having isotropic thermal properties by electrostatic force, a method of manufacturing the same, and a heat dissipation material including the same.

According to the present disclosure, compared to the comparative examples, thermal conductivity in the vertical direction of the heat source may be increased and the selection of thermal conductivity (Kin-plane/Kthrough-plane) may be decreased, enabling various applications. Kin-plane means horizontal thermal conductivity, and Kthrough-plane means vertical thermal conductivity. In addition, by increasing the amount of the anisotropic material, the Kin-plane and Kthrough-plane values as well as the ratio of Kin-plane/Kthrough-plane may be adjusted, facilitating heat control. In particular, when a hot spot occurs in which heat is concentrated in a specific area of the electrostatic chuck 20, the heat dissipation material of the present disclosure may be applied, greatly improving heat conduction performance.

As the anisotropic particles, various materials may be used, such as BN with insulating properties, CNTs (carbon nanotubes) with electrical conductivity, CNF (cellulose nanofiber) capable of complementing mechanical and thermal properties of the polymer matrix, etc., so the application fields are diverse.

For the hybrid particles 330 according to the present disclosure, high densification is possible in a short period of time in manufacturing a polymer composite or a sintered body by virtue of easy packing of particles, thereby increasing process efficiency.

The present disclosure provides a heat dissipation material provided to an electrostatic chuck 20 supporting a substrate W in a substrate processing apparatus 1 using plasma. The heat dissipation material according to the present disclosure includes hybrid particles 330 formed by mixing a first particle dispersion L1 treated to charge the surface of isotropic particles 310 with a first electric potential and a second particle dispersion L2 treated to charge the surface of anisotropic particles 320 with a second electric potential different from the first electric potential and configured to include the isotropic particles 310 and the anisotropic particles 320 bound by electrostatic force.

In the substrate processing apparatus 1 using plasma according to the present disclosure, the electrostatic chuck 20 configured to support the substrate W includes a base plate 115 made of a metal material having a cooling path 122 formed inside through which a cooling fluid flows, an adhesive layer 120 formed on the base plate 115, and a support plate 110 made of a ceramic material adhered onto the base plate 115 through the adhesive layer 120 and having heaters 114 installed inside for heating the substrate W. The heat dissipation material is attached to transfer heat from the support plate 110 or the base plate 115 to the substrate W.

The heat dissipation material according to the present disclosure may be applied onto the upper surface of the support plate 110 or onto the adhesive layer 120.

A plurality of protrusions coming into contact with the substrate W may be arranged on the upper surface of the support plate 110, and the heat dissipation material according to the present disclosure may be applied onto the protrusions, or the protrusions may include the heat dissipation material according to the present disclosure. The heat dissipation material according to the present disclosure may be applied onto the upper or lower surface of the adhesive layer 120, or the adhesive layer 120 may include the heat dissipation material according to the present disclosure.

The heat dissipation material according to the present disclosure may be used for heat management or hot spot removal in not only the electrostatic chuck 20, but also various electronic devices and parts, batteries for electric vehicles, display parts such as OLEDs (organic light emitting diodes), circuits for various power sources, semiconductor process equipment, etc.

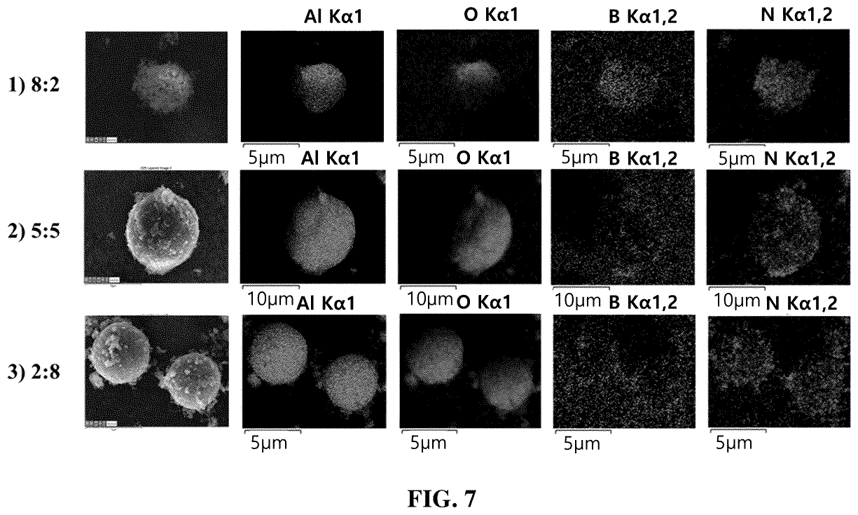

FIG. 7 shows electron dispersive spectroscopy (EDS) images of hybrid particles depending on the mass ratio of the isotropic particles to the anisotropic particles. In FIG. 7, the first line shows EDS images of hybrid particles at 8:2 as the mass ratio of the anisotropic particles to the isotropic particles, the second line shows EDS images of hybrid particles at 5:5 as the mass ratio of the anisotropic particles to the isotropic particles, and the third line shows EDS images of hybrid particles at 2:8 as the mass ratio of the anisotropic particles to the isotropic particles.

By manufacturing the hybrid particles depending on the mass ratio of the anisotropic particles to the isotropic particles and employing a film using the hybrid particles, the direction in which heat is transferred, as indicated by the arrow in FIG. 6, may be advantageously controlled. For example, as the mass proportion of the anisotropic particles relatively increases, the direction of heat transfer may be closer to the horizontal direction (left-right direction) rather than the vertical direction (up-down direction). As the mass proportion of the isotropic particles relatively increases, the direction of heat transfer may be closer to the vertical direction (up-down direction) rather than the horizontal direction (left-right direction).

As is apparent from the foregoing, according to the present disclosure, heat transfer efficiency is increased in horizontal and vertical directions by forming hybrid particles including isotropic particles and anisotropic particles bound by electrostatic force, so that heat conduction in the electrostatic chuck can be improved and the temperature of the substrate can be distributed uniformly.

The present embodiments and the drawings attached to the present specification are merely intended to clearly illustrate a portion of the technical spirit included in the present disclosure, and it will be obvious that all modifications and specific embodiments that may be easily inferred by those skilled in the art within the scope of the technical spirit included in the specification and drawings of the present disclosure are included in the scope of the rights of the present disclosure.

Therefore, the spirit of the present disclosure should not be limited to the described embodiments, and the following claims and also all modifications equivalent to the claims are included in the scope of the spirit of the present disclosure.

What is claimed is:

1. A method of manufacturing a heat dissipation material provided to an electrostatic chuck supporting a substrate in a substrate processing apparatus using plasma, comprising:
forming a first particle dispersion treated to charge a surface of isotropic particles with a first electric potential;
forming a second particle dispersion treated to charge a surface of anisotropic particles with a second electric potential different from the first electric potential; and
forming hybrid particles comprising the isotropic particles and the anisotropic particles bound by electrostatic force by mixing the first particle dispersion and the second particle dispersion.

2. The method according to claim 1, wherein the isotropic particles comprise a metal comprising at least one of Cu, Al, or Ag, or a ceramic comprising at least one of Al₂O₃, AlN, or SiC.

3. The method according to claim 1, wherein the anisotropic particles are BN (boron nitride), or comprise at least one of CNTs (carbon nanotubes) or CNF (cellulose nanofiber).

4. The method according to claim 1, wherein forming the second particle dispersion comprises:
attaching at least one functional group of OH-, F-, or NH2- to the surface of the anisotropic particles; and
performing surface modification by exfoliating a hexagonal crystal plane from the anisotropic particles with the functional group attached thereto.

5. The method according to claim 1, wherein a major axis length of the anisotropic particles is 1 nm to 1000 nm.

6. The method according to claim 1, wherein an aspect ratio of the anisotropic particles is 10 to 1000.

7. The method according to claim 1, wherein a grain size of a (002) plane of the anisotropic particles is 5 Å to 500 Å in X-ray diffraction analysis.

8. The method according to claim 1, wherein a volume ratio of the isotropic particles to the anisotropic particles in the hybrid particles is 2:98 to 98:2.

9. The method according to claim 1, wherein the heat dissipation material is manufactured in a form of a grease, a gap filler, or an adhesive by mixing a polymer matrix and a solvent with the hybrid particles to afford a slurry and aging the slurry.

10. The method according to claim 1, wherein the heat dissipation material is manufactured in a form of a film, a sheet, a pad, or a plate by mixing a polymer matrix and a solvent with the hybrid particles to afford a slurry and subjecting the slurry to extrusion molding, compounding, thermoforming, or compression coating.

11. The method according to claim 1, wherein the heat dissipation material is manufactured in a form of a sintered body by subjecting the hybrid particles to a hot isostatic process (HIP) or plasma spraying.

12. A heat dissipation material provided to an electrostatic chuck supporting a substrate in a substrate processing apparatus using plasma, comprising:
hybrid particles formed by mixing a first particle dispersion treated to charge a surface of isotropic particles with a first electric potential and a second particle dispersion treated to charge a surface of anisotropic particles with a second electric potential different from the first electric potential and configured to comprise the isotropic particles and the anisotropic particles bound by electrostatic force.

13. The heat dissipation material according to claim 12, wherein the isotropic particles are a metal comprising at least one of Cu, Al, or Ag, or a ceramic comprising at least one of Al₂O₃, AlN, or SiC.

14. The heat dissipation material according to claim 12, wherein the anisotropic particles are BN (boron nitride) having a hexagonal crystal structure, or comprise at least one of CNTs (carbon nanotubes) or CNF (cellulose nanofiber).

15. The heat dissipation material according to claim 12, wherein a major axis length of the anisotropic particles is 1 nm to 1000 nm.

16. The heat dissipation material according to claim 12, wherein an aspect ratio of the anisotropic particles is 10 to 1000.

17. The heat dissipation material according to claim 12, wherein a grain size of a (002) plane of the anisotropic particles is 5 Å to 500 Å in X-ray diffraction analysis of the anisotropic particles.

18. The heat dissipation material according to claim 12, wherein a volume ratio of the isotropic particles to the anisotropic particles in the hybrid particles is 2:98 to 98:2.

19. An electrostatic chuck supporting a substrate in a substrate processing apparatus using plasma, comprising:
a base plate made of a metal material having a cooling path formed inside through which a cooling fluid flows;
an adhesive layer disposed on the base plate; and
a support plate made of a ceramic material adhered onto the base plate through the adhesive layer and having a heater installed inside for heating the substrate,
wherein a heat dissipation material is attached to transfer heat from the support plate or the base plate to the substrate,
the heat dissipation material comprises hybrid particles comprising isotropic particles and anisotropic particles bound by electrostatic force by mixing a first particle dispersion treated to charge a surface of the isotropic particles with a first electric potential and a second particle dispersion treated to charge a surface of the anisotropic particles with a second electric potential different from the first electric potential,
the isotropic particles comprise a metal comprising at least one of Cu, Al, or Ag, or a ceramic comprising at least one of Al₂O₃, AlN, or SiC,
the anisotropic particles are BN (boron nitride) having a hexagonal crystal structure, or comprise at least one of CNTs (carbon nanotubes) or CNF (cellulose nanofiber),
a major axis length of the anisotropic particles is 1 nm to 1000 nm,
an aspect ratio of the anisotropic particles is 10 to 1000,
a grain size of a (002) plane of the anisotropic particles is 5 Å to 500 Å in X-ray diffraction (XRD) analysis of the anisotropic particles, and
a volume ratio of the isotropic particles to the anisotropic particles in the hybrid particles is 2:98 to 98:2.

20. The electrostatic chuck according to claim 19, wherein the heat dissipation material is applied onto an upper surface of the support plate or onto the adhesive layer.
